(19) United States
(12) Patent Application Publication
(10) Pub. No.: US 2024/0150897 A1
(43) Pub. Date: May 9, 2024

(54) HEATER ASSEMBLY, SUBSTRATE PROCESSING APPARATUS, AND METHOD OF MANUFACTURING SEMICONDUCTOR DEVICE

(71) Applicant: Kokusai Electric Corporation, Tokyo (JP)

(72) Inventors: Makoto KAWABATA, Toyama-shi (JP); Tomoyuki Yamada, Toyama-shi (JP)

(73) Assignee: Kokusai Electric Corporation, Tokyo (JP)

(21) Appl. No.: 18/417,671

(22) Filed: Jan. 19, 2024

Related U.S. Application Data
(63) Continuation of application No. PCT/JP21/27285, filed on Jul. 21, 2021.

(51) Int. Cl. C23C 16/455; C23C 16/52; H01L 21/02; H05B 3/36

(52) U.S. Cl. CPC C23C 16/45561; C23C 16/52; H01L 21/02271; H05B 3/36

(57) ABSTRACT

A heater assembly includes: a first heater sheet including a first electric heater having no self-controllability and a first insulator electrically insulating and surrounding the first electric heater, the first heater sheet being deformable in accordance with a shape of a heating target; and one or more second heater sheets each including one or more second electric heaters having self-controllability and a second insulator electrically insulating and surrounding the one or more second electric heaters, the one or more second heater sheets being deformable in accordance with the shape of the heating target.

### CROSS-REFERENCE TO RELATED APPLICATION

This application is a Bypass Continuation Application of PCT International Application No. PCT/JP2021/027285, filed on Jul. 21, 2021, the entire contents of which are incorporated herein by reference.

### BACKGROUND

### Field

The present disclosure relates to a heater assembly, a substrate processing apparatus, and a method of manufacturing a semiconductor device.

### Description of the Related Art

A semiconductor device manufacturing process may involve forming a film on a substrate mounted in a process container while heating the interior of the process container by a heater.

Furthermore, a technique of heating a pipe and a furnace opening through which a gas is fed into the process container may be employed in order to suppress temperature unevenness in the process container.

### SUMMARY

The present disclosure provides a technique capable of making a temperature of a heating target uniform.

According to an embodiment of the present disclosure, there is provided a technique that includes:
a first heater sheet including
   a first electric heater having no self-controllability and
   a first insulator electrically insulating and surrounding the first electric heater,
the first heater sheet being deformable in accordance with a shape of a heating target; and
one or more second heater sheets each including
   one or more second electric heaters having self-controllability and
   a second insulator electrically insulating and surrounding the one or more second electric heaters,
the one or more second heater sheets being deformable in accordance with the shape of the heating target.

### BRIEF DESCRIPTION OF THE DRAWINGS

FIG. 1 is a vertical sectional view schematically illustrating a vertical processing furnace of a substrate processing apparatus according to an embodiment of the present disclosure.

FIG. 2 is a diagram illustrating a functional configuration of a controller of the substrate processing apparatus according to the embodiment of the present disclosure.

FIG. 3 is a flowchart illustrating a substrate processing process according to the embodiment of the present disclosure.

FIG. 4A is an enlarged view of a region A illustrated in FIG. 1.

FIG. 4B is a sectional view taken along line A-1-A-1 illustrated in FIG. 4A.

FIG. 4C is a partially enlarged view illustrating a configuration of a pipe heater illustrated in FIG. 4A.

FIG. 5 is a block diagram illustrating the configuration of the pipe heater according to the present disclosure.

FIG. 6 is a diagram illustrating a modified example of a second heater sheet according to an embodiment of the present disclosure.

FIG. 7 is a diagram illustrating a modified example of a second heater sheet according to an embodiment of the present disclosure.

### DETAILED DESCRIPTION

### (1) Configuration of Substrate Processing Apparatus

One or more embodiments will be described below with reference to the drawings. In the following, identical constituents are denoted by the same reference sign, and the repeated description thereof may therefore be omitted. It should be noted that the drawings may schematically illustrate the width, thickness, shape, and the like of each constituent for a better understanding of the following description; therefore, the width, thickness, shape, and the like may be different from actual ones. It is understood that the illustration is merely exemplary and is not intended to limit the interpretation of the present disclosure.

### (Processing Furnace)

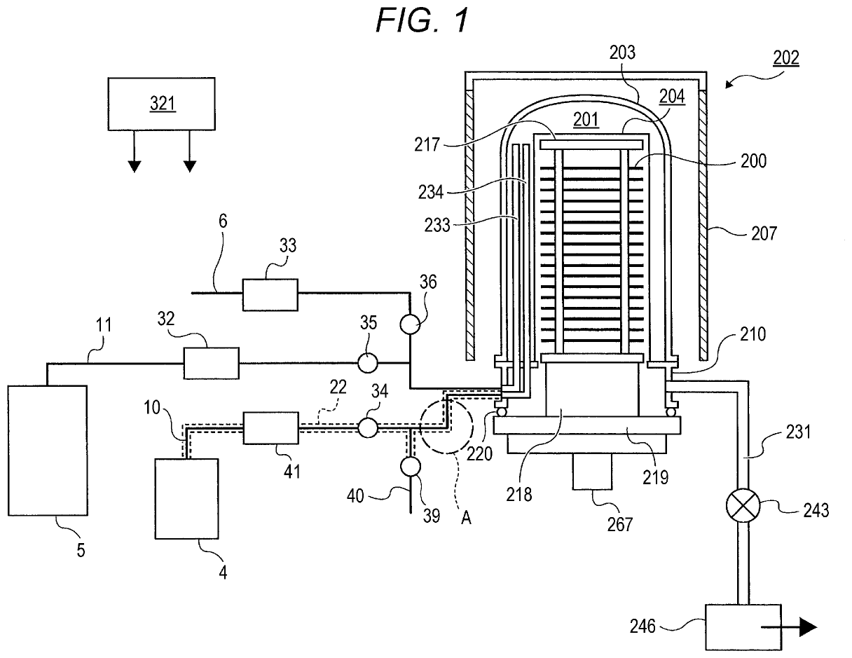

As illustrated in FIG. 1, a reaction tube 203 is provided inside a heater 207. The reaction tube 203 serves as a process container that subjects a wafer 200 to processing. The wafer 200 serves as a substrate. An inlet flange 210 is provided on a lower end of the reaction tube 203. The inlet flange 210 serves as a furnace opening. The inlet flange 210 is hermetically closed by a seal cap 219 with an O-ring 220 interposed between the inlet flange 210 and the seal cap 219. The seal cap 219 serves as a lid. The O-ring 220 serves as a hermetic seal. An inner tube 204 is mounted on the inlet flange 210. A process chamber 201 is constituted of at least the reaction tube 203, the inner tube 204, the inlet flange 210, and the seal cap 219. A boat 217 is placed on the seal cap 219 with a quartz cap 218 interposed between the boat 217 and the seal cap 219. The boat 217 serves as a substrate holder. The quartz cap 218 and the boat 217 are loaded into and unloaded from the process chamber 201. A plurality of wafers 200 are horizontally stacked in multiple stages on the boat 217, and are subjected to batch processing. The heater 207 heats the wafers 200 inserted in the process chamber 201, to a predetermined temperature.

The process chamber 201 communicates with a gas pipe 10 through which a first process gas (a raw material gas) is fed and a gas pipe 11 through which a second process gas (a reactant gas) is fed. The gas pipe 10 as a part of piping is provided with a gas feeder (gas source) 4 that feeds the raw material gas (i.e., the first process gas), a mass flow controller (MFC) 41 that controls a flow rate of the raw material gas from the gas feeder 4, and a valve 34 that opens and closes a raw material gas flow path. The gas feeder 4, the MFC 41, and the valve 34 are arranged in this order from the upstream side of the gas pipe 10. The gas feeder 4 feeds the raw material gas into the process chamber 201 through the gas pipe 10 via the MFC 41, the valve 34, and a nozzle 234 placed in the process chamber 201. The gas pipe 10, the MFC 41, the valve 34, and the nozzle 234 constitute a first process gas feed system (also referred to as a raw material gas feed system).

The gas pipe 11 is provided with a gas feeder 5 that feeds the reactant gas (i.e., the second process gas), an MFC 32 that controls a flow rate of the reactant gas from the gas feeder 5, and a valve 35 that opens and closes a reactant gas flow path. The gas feeder 5, the MFC 32, and the valve 35 are arranged in this order from the upstream side of the gas pipe 11. The gas feeder 5 feeds the reactant gas into the process chamber 201 through the gas pipe 11 via the MFC 32, the valve 35, and a nozzle 233 placed in the process chamber 201. The gas pipe 11, the MFC 32, the valve 35, and the nozzle 233 constitute a second process gas feed system (also referred to as a reactant gas feed system).

A pipe heater 22 is provided around the gas pipe 10 connecting the gas feeder 4 and the process chamber 201. The pipe heater 22 heats the gas pipe 10 that serves as a heating target. As will be described in detail later, the pipe heater 22 serves as a heater assembly including a first heater sheet and a second heater sheet. Each of the first heater sheet and the second heater sheet is a sheet-shaped heater.

A gas pipe 40 is connected to the gas pipe 10 at a position downstream of the valve 34. The gas pipe 40 is provided with a valve 39, and an inert gas is fed through the gas pipe 40. The pipe heater 22 also covers a range from the valve 39 to a joint between the gas pipe 40 and the gas pipe 10. A gas pipe 6 is connected to the gas pipe 11 at a position downstream of the valve 35. The gas pipe 6 is provided with an MFC 33 and a valve 36, and an inert gas is fed through the gas pipe 6.

Each of the gas pipes 10 and 40 is a pipe through which a gas is fed to the process chamber 201 where the wafers 200 are subjected to processing. Each of the gas pipes 10 and 40 has a nominal diameter that is not more than 25 mm. Semiconductor process gas feed pipes typically have nominal diameters of 8 mm, 10 mm, 15 mm, 20 mm, and 25 mm (i.e., ¼ inches, ⅜ inches, ½ inches, ¾ inches, and 1 inch). In addition, these pipes are typically 0.71 mm to 2.11 mm in thickness.

In this embodiment, the second process gas feed system does not include a pipe heater. However, the second process gas feed system may include the pipe heater 22 according to this embodiment as appropriate in accordance with the type of the second process gas.

An exhaust pipe 231 connects the process chamber 201 and a vacuum pump 246. The exhaust pipe 231 serves as an exhaust-side pipe through which a gas is discharged, and is provided with an automatic pressure control (APC) valve 243. The exhaust pipe 231, the APC valve 243, and the vacuum pump 246 constitute a gas exhaust system.

The nozzle 234 is placed to extend upward in the vertical direction from a position below the reaction tube 203. The nozzle 234 has a plurality of gas feed holes through which the raw material gas is distributed and fed. These gas feed holes are located between opposite two of the wafers 200 with the inner tube 204 interposed between the gas feed holes and the wafers 200. The process gas is distributed and fed to the wafers 200 through the gas feed holes. The nozzle 233 is placed as in the nozzle 234 at a position separate from the nozzle 234 in the circumferential direction of the reaction tube 203. The nozzle 233 also has a plurality of gas feed holes. The nozzle 234 communicates with the gas pipe 10 to distribute and feed, into the process chamber 201, the raw material gas and the inert gas supplied through the gas pipe 40 connected to the gas pipe 10. In addition, the nozzle 233 communicates with the gas pipe 11 to distribute and feed, into the process chamber 201, the reactant gas and the inert gas supplied through the gas pipe 6 connected to the gas pipe 11. A film is formed in such a manner that the process gases are alternately fed from the nozzles 234 and 233 into the process chamber 201.

The boat 217 is provided in the inner tube 204. On the boat 217, the plurality of wafers 200 are mounted in multiple stages at equal intervals. A boat elevator allows the boat 217 to be loaded into and unloaded from the process chamber 201. A boat rotator 267 is provided to subject the plurality of wafers 200 to processing more uniformly. The boat rotator 267 serves as a rotator that rotates the boat 217. The boat rotator 267 rotates and, accordingly, the boat 217 held by the quartz cap 218 also rotates.

### (Functional Configuration of Controller 321)

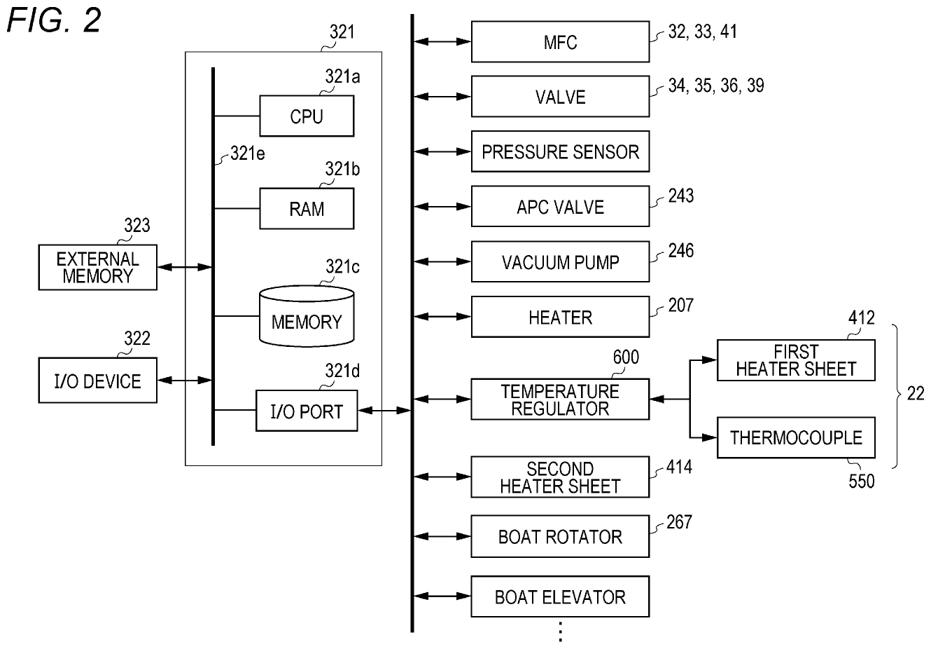

With reference to FIG. 2, next, a description will be given of a controller 321.

The controller 321 is practicable using a computer including a central processing unit (CPU) 321a, a random access memory (RAN) 321b, a memory 321c, and an input/output (I/O) port 321d. Data is exchangeable between the CPU 321a and each of the RAM 321b, the memory 321c, and the I/O port 321d via an internal bus 321e. The controller 321 is connected to an I/O device 322 practicable using, for example, a touch panel or the like.

The memory 321c is practicable using, for example, a flash memory or the like. The memory 321c stores, for example, a control program that controls operation of the substrate processing apparatus, and a process recipe that contains procedures, conditions, and the like of substrate processing (to be described later). The control program, the process recipe, and the like are readable from the memory 321c. It should be noted that the process recipe is combined to cause the controller 321 to execute procedures in a substrate processing process including a substrate loading step S102, a film forming step S104, and a substrate unloading step S106 (to be described later), thereby obtaining a predetermined result. The RAM 321b serves as a memory area (a work area) where a program, data, and the like read by the CPU 321a are temporarily retained.

The I/O port 321d is connected to, for example, the MFCs 32, 33, and 41, the valves 34, 35, 36, and 39, a pressure sensor, the APC valve 243, the vacuum pump 246, the heater 207, a temperature regulator 600, a first heater sheet 412, a thermocouple 550, a second heater sheet 414, the boat rotator 267, and the boat elevator. The thermocouple 550 serves as a temperature sensor.

The CPU 321a is configured to read the control program from the memory 321c and to execute the control program. The CPU 321a is also configured to read the process recipe from the memory 321c in accordance with, for example, input of an operation command through the I/O device 322 that serves as an operation display. In addition, the CPU 321a is configured to control, for example, operation of adjusting the flow rates of the gases by the MFCs 32, 33, and 41, operation of opening and closing the valves 34, 35, 36, and 39, operation of opening and closing the APC valve 243, operation of adjusting, by the APC valve 243, a pressure detected by the pressure sensor, operation of adjusting a temperature of the heater 207, operation of regulating, by the temperature regulator 600, a temperature of the first heater sheet 412 detected by the thermocouple 550, operation of controlling a temperature of the second heater sheet 414 by the second heater sheet 414 itself, operation of starting and stopping the vacuum pump 246, operation of rotating the boat 217 by the boat rotator 267, operation of adjusting a rotating speed of the boat 217 by the boat rotator 267, and operation of moving up and down the boat 217 by the boat elevator, in conformity with the contents of the process recipe thus read.

It should be noted that the controller 321 is practicable using a computer that installs therein the foregoing program stored in an external memory (e.g., a semiconductor memory such as a USB thumb drive or a memory card) 323. Each of the memory 321c and the external memory 323 is practicable as a non-transitory computer-readable recording medium. These memories are also collectively referred to simply as a recording medium below. The term “recording medium” as used herein may refer to the memory 321c, the external memory 323, or both the memory 321c and the external memory 323. The computer may receive the program using a communication tool, such as the Internet or a dedicated line, in place of the external memory 323.

### (2) Substrate Processing Process

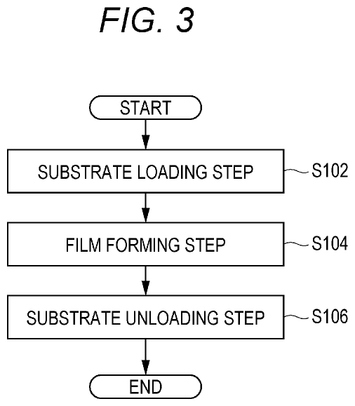

With reference to FIG. 3, next, a description will be given of the outline of the substrate processing process included in a semiconductor device manufacturing process, using the substrate processing apparatus. The substrate processing process is a method of processing a substrate. The semiconductor device manufacturing process is a method of manufacturing a semiconductor device. The substrate processing apparatus serves as a semiconductor manufacturing apparatus. The substrate processing process is, for example, a process of manufacturing a semiconductor device. It should be noted that the following operation of and processing by each constituent of the substrate processing apparatus are controlled by the controller 321.

The following describes an example of forming a film on each wafer 200 that serves as a substrate, by alternately feeding the first process gas (i.e., the raw material gas) and the second process gas (i.e., the reactant gas) to the wafer 200. Specifically, the following describes an example of forming a silicon nitride (SiN) film as a thin film on each wafer 200, using a silicon (Si) raw material gas as the raw material gas and an ammonia (NH₃) gas as the reactant gas. The Si raw material gas is a Si-containing raw material gas and is in the form of a liquid at normal temperature. The NH₃ gas is a N-containing raw material gas. For example, a predetermined film may be previously formed on each wafer 200. Furthermore, a predetermined pattern may be previously formed on the wafer 200 or the predetermined film.

### (Substrate Loading Step S102)

First, the substrate loading step S102 is carried out. The substrate loading step S102 involves mounting each wafer 200 on the boat 217 and loading the wafer 200 into the process chamber 201.

### (Film Forming Step S104)

Next, the film forming step S104 is carried out. The film forming step S104 involves forming a thin film on a surface of the wafer 200. The film forming step includes the following four steps to be carried out in succession. It should be noted that the heater 207 heats the wafer 200 to a predetermined temperature during steps 1 to 4. In addition, the pipe heater 22 heats the gas pipe 10 and a part of the gas pipe 40 to a predetermined set temperature. The predetermined set temperature is set as appropriate in accordance with the type of the raw material gas. In this embodiment, the raw material gas is a gas obtained by vaporizing a liquid material. Therefore, the predetermined set temperature is, for example, not less than 180° C. in order to inhibit the raw material gas from being liquefied in the film forming step S104.

### [Step 1]

Step 1 involves feeding the Si raw material gas. First, the valve 34 on the gas pipe 10 and the APC valve 243 on the exhaust pipe 231 are opened. The Si raw material gas of which the flow rate has been adjusted by the MFC 41 is fed from the gas feeder 4 through the gas pipe 10. The Si raw material gas is then fed into the process chamber 201 through the gas feed holes in the nozzle 234. The Si raw material gas is also discharged through the exhaust pipe 231. At this time, the pipe heater 22 heats the gas pipe 10 and a part of the gas pipe 40 to a predetermined temperature. At this time, further, the pressure in the process chamber 201 is maintained at a predetermined pressure. A Si thin film is thus formed on the surface of the wafer 200.

### [Step 2]

Step 2 involves closing the valve 34 on the gas pipe 10 to stop the feed of the Si raw material gas. The APC valve 243 on the exhaust pipe 231 is still open. The vacuum pump 246 discharges the residual gas from the process chamber 201. In addition, the valve 39 on the gas pipe 40 is opened. The inert gas such as N₂ is thus fed into the process chamber 201 through the gas pipe 40 to thereby purge the process chamber 201, so that the residual gas is discharged from the process chamber 201. Furthermore, the valve 36 on the gas pipe 6 is opened. The inert gas such as N₂ of which the flow rate has been adjusted by the MFC 33 is also fed into the process chamber 201 through the gas pipe 6.

### [Step 3]

Step 3 involves feeding the NH₃ gas. First, the valve 35 on the gas pipe 11 and the APC valve 243 on the exhaust pipe 231 are opened. The NH₃ gas of which the flow rate has been adjusted by the MFC 32 is fed from the gas feeder 5 through the gas pipe 11. The NH₃ gas is then fed into the process chamber 201 through the gas feed holes in the nozzle 233. The NH₃ gas is also discharged through the exhaust pipe 231. At this time, the pressure in the process chamber 201 is adjusted to a predetermined pressure. Feeding the NH₃ gas causes a reaction between the NH₃ gas and the Si thin film formed on the surface of the wafer 200 with the Si raw material gas, so that a SiN film is formed on the wafer 200.

### [Step 4]

Step 4 involves purging the process chamber 201 using the inert gas again. The valve 35 on the gas pipe 11 is closed to stop the feed of the NH₃ gas. The APC valve 243 on the exhaust pipe 231 is still open. The vacuum pump 246 discharges the residual gas from the process chamber 201. Furthermore, the valve 36 on the gas pipe 6 is opened. The inert gas such as N₂ of which the flow rate has been adjusted by the MFC 33 is fed into the process chamber 201 through the gas pipe 6 to thereby purge the process chamber 201. The valve 39 on the gas pipe 40 is also opened. The inert gas such as N₂ is also fed into the process chamber 201 through the gas pipe 40.

A series of steps 1 to 4 is carried out multiple times to form a SiN film having a predetermined thickness on the wafer 200.

### (Substrate Unloading Step S106)

Next, the boat 217 is unloaded from the process chamber 201 with the wafer 200, on which the SiN film has been formed, mounted on the boat 217.

According to this embodiment, the raw material gas (i.e., the Si raw material gas) is fed to the process chamber 201 through the gas pipe 10 at least heated by the pipe heater 22. This configuration therefore suppresses liquefaction of the raw material gas and inhibits a gas containing particles from being fed to the process chamber 201. In other words, a saturated vapor pressure increases in accordance with a temperature rise, resulting in increases of a pressure and an amount feedable without occurrence of liquefaction. Desirably, the gas pipe 10 is heated at a uniform temperature from the upstream side to the downstream side or is heated with temperature distribution that gently rises toward the downstream side. Temperature unevenness may cause a situation in which the gas pipe 10 becomes lower in temperature than the raw material gas. This results in a possibility of liquefaction. In a case where the length of each of the gas pipes 10 and 40 is long, the pipe heater 22 may be provided in a divided manner.

In this embodiment, the pipe heater 22 at least continuously heats the gas pipe 10 and the gas pipe 40 to keep the predetermined set temperature during the series of steps 1 to 4 carried out multiple times.

### (3) Configuration of Pipe Heater 22

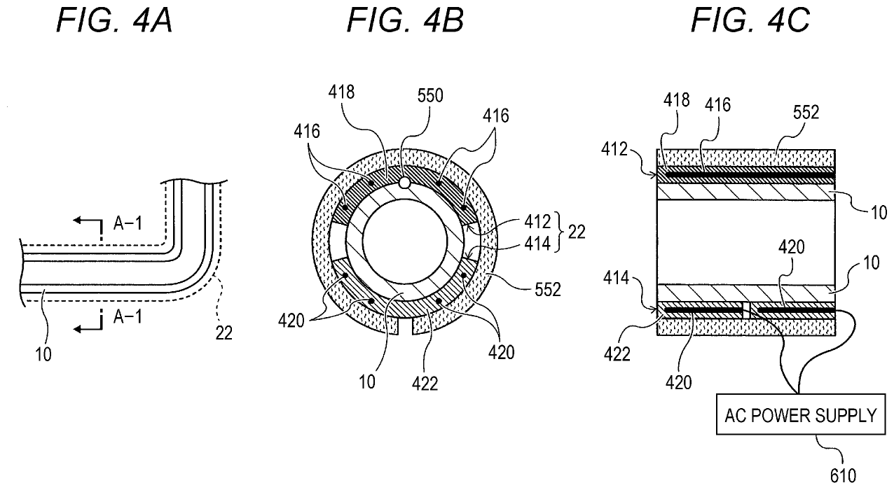

With reference to FIGS. 4A to 4C, next, a description will be given of the details of the pipe heater 22 according to this embodiment. The following description is given using the pipe heater 22 provided around the gas pipe 10.

The pipe heater 22 includes a first heater sheet 412 and one or more second heater sheets 414. Each of the first heater sheet 412 and the second heater sheets 414 has a sheet shape and is deformable in accordance with the shape of the gas pipe 10 that serves as a heating target. In practical use, the first heater sheet 412 and the second heater sheets 414 are wound around the gas pipe 10 made of a metal material such as stainless steel.

The gas pipe 10 includes a linear section and a bent section, and allows a fluid to pass therethrough. That is, the gas pipe 10 includes a bent portion, and the first heater sheet 412 and the second heater sheets 414 are respectively disposed to face an inner side and an outer side of the bent portion of the gas pipe 10. In other words, the first heater sheet 412 and the second heater sheets 414 are disposed to face each other with the gas pipe 10 sandwiched therebetween. That is, the second heater sheets 414 are disposed opposite the first heater sheet 412 across the gas pipe 10. Alternatively, the first heater sheet 412 and the second heater sheets 414 may be respectively disposed to face the outer side and the inner side of the bent portion of the gas pipe 10. As described above, the first heater sheet 412 and the second heater sheets 414 are respectively disposed on the inner side and the outer side of the bent portion of the gas pipe 10. As a result, the respective heater sheets are different lengths between the inner side and the outer side of the bent portion and are thus brought into close contact with the gas pipe 10 reliably. This configuration therefore makes a temperature of the heated gas pipe more uniform even when the gas pipe has a complicated shape.

The first heater sheet 412 may have a width that is substantially equal to or slightly shorter than a half of an outer periphery of the gas pipe 10. In addition, the first heater sheet 412 may be provided with its lengthwise direction defined parallel to the direction in which the gas pipe 10 extends.

The first heater sheet 412 includes a first electric heater 416 and a first insulator 418 electrically insulating and surrounding the first electric heater 416. The first electric heater 416 is a heat generating wire. The first electric heater 416 is, for example, a nichrome wire that dissipates heat generated by energization. The first insulator 418 is, for example, a film or a glass cloth made of a polyimide or fluoroethylene polymer. For example, polytetrafluoroethylene (PTFE) or the like is used. The first heater sheet 412 is in close contact with the gas pipe 10 in the lengthwise direction of the gas pipe 10.

Each second heater sheet 414 may have a width that is substantially equal to or slightly shorter than the half of the outer periphery of the gas pipe 10. In addition, each second heater sheet 414 may be provided with its lengthwise direction defined parallel to the direction in which the gas pipe 10 extends.

Each second heater sheet 414 includes a second electric heater 420 and a second insulator 422 electrically insulating and surrounding the second electric heater 420. The second electric heater 420 is one or more heat generating wires having self-controllability. The term “self-control” as used herein refers to a function of automatically increasing and decreasing a calorific value in accordance with a temperature. More specifically, the calorific value of the second electric heater 420 is autonomously subjected to negative feedback control by increasing or decreasing the resistance value in accordance with the temperature of the second electric heater 420, so that the temperature of the second electric heater 420 may become stabilized against a change in environment. It should be noted that a heater having self-controllability, such as the second heater sheets 414, can also be referred to as an auto-trace heater.

The second electric heater 420 is a resistance wire or a metallized film that is higher in positive temperature coefficient than the first electric heater 416. For example, the second electric heater 420 may be made of an alloy of nickel (70%) and iron (30%) called MWS-120. The second electric heater 420 has an electric resistance of which the positive temperature coefficient is not less than 0.5%/° C., more preferably not less than 1%/° C., at a predetermined set temperature. The resistance value of the second electric heater 420 and the voltage to be applied to the second electric heater 420 are set such that the second electric heater 420 changes, by self-control, the heat by the second electric heater 420 from a set temperature to a predetermined temperature, for example, a temperature that is lower by 20° C. to 30° C. than the set temperature. Specifically, in a case where the set temperature is 180° C., the resistance value and the like are selected such that a calorific value when the heat by the second electric heater 420 is 150° C. to 160° C. becomes equal to or not more than a calorific value for heating the gas pipe 10 to 180° C., and more preferably becomes 50% to 70% of the calorific value. As described above, the heat by each second heater sheet 414 is set at a temperature lower than the set temperature and is adjusted to the set temperature by the first heater sheet 412 including the thermocouple 550. This configuration thus makes the temperature of the gas pipe 10 more uniform.

The second insulator 422 is, for example, a film or a glass cloth made of a polyimide or fluoroethylene polymer. For example, PTFE is used. The second heater sheets 414 are in close contact with the gas pipe 10 in the lengthwise direction of the gas pipe 10.

That is, the heat generating wire of the first heater sheet 412 is different from the heat generating wire of each second heater sheet 414. Preferably, the insulator of the first heater sheet 412 is equal in material to the insulator of each second heater sheet 414. The first electric heater 416, the first insulator 418, the second electric heater 420, and the second insulator 422 are each made of a flexible material. Therefore, the first heater sheet 412 and each second heater sheet 414, having flexibility, are bendable in both the lengthwise direction and the widthwise direction, and are deformable in accordance with the shape of the gas pipe 10. In order that the first heater sheet 412 and each second heater sheet 414 can be bent with ease, the first insulator 418 and the second insulator 422 may have a groove or a slit to an extent that does not impair the insulating performance.

Preferably, the first heater sheet 412 and the second heater sheets 414 are substantially equal to each other in a width, that is, a length in a direction perpendicular to the lengthwise direction. Also preferably, the first heater sheet 412 and the second heater sheets 414 are equal to each other in at least one of a material for the insulators, a lateral width, and a thickness. Also preferably, the first heater sheet 412 and the second heater sheets 414 have the same shape. When the first heater sheet 412 and second heater sheets 414 of the pipe heater 22 are made equal in shape and material to each other as described above, the temperature of the gas pipe can be made more uniform, and the manufacturing cost can be reduced.

The first heater sheet 412 and the second heater sheets 414 each have the width substantially corresponding to the half of the outer periphery of the gas pipe 10. In addition, the first heater sheet 412 and the second heater sheets 414 are disposed with their lengthwise directions defined parallel to the lengthwise direction of the gas pipe 10. According to this configuration, substantially the entire outside surface of the gas pipe 10 are brought into contact with the first heater sheet 412 or the second heater sheets 414. A distance between a widthwise center line of the first heater sheet 412 and a widthwise center line of each second heater sheet 414 is measured along the outside surface of the gas pipe 10. This distance is not more than a half of an outer peripheral length of the gas pipe 10. Alternatively, this distance is not more than 20 times the thickness of the gas pipe 10. According to this configuration, the temperature deviation of the gas pipe 10 can be satisfactorily reduced by the heat conduction of the gas pipe 10 itself even when the first heater sheet 412 and the second heater sheets 414 are different in calorific value or temperature per unit area from each other as will be described later. The foregoing distance is preferably short as much as possible from the viewpoint of making the temperature of the gas pipe uniform.

A heat insulator 552 is provided on the outer side of each of the first heater sheet 412 and the second heater sheets 414. That is, the heat insulator 552 covers the gas pipe 10 together with the first heater sheet 412 and the second heater sheets 414. In other words, each of the first heater sheet 412 and the second heater sheets 414 has an outer periphery covered with and surrounded by the heat insulator 552. The heat insulator 552 is fixed using a cable tie or the like (not illustrated). The first heater sheet 412 and the second heater sheets 414 are maintained in a state in which the first heater sheet 412 and the second heater sheets 414 fit to the gas pipe 10.

As illustrated in FIG. 4B, the thermocouple 550 is provided between the first heater sheet 412 and the gas pipe 10 at a position inward of the heat insulator 552 and the first heater sheet 412. The thermocouple 550 is thermally coupled to the gas pipe 10 or the first electric heater 416. The thermocouple 550 is separable from the first heater sheet 412 and is configured to detect a temperature of the gas pipe 10. The thermocouple 550 is brought into contact with the gas pipe 10 and is thus thermally coupled to the gas pipe 10. One thermocouple 550 is provided in correspondence with one first heater sheet 412. That is, a degree of energization of each second heater sheet 414 is not detected and controlled by a thermocouple.

As illustrated in FIG. 4C, for example, two second heater sheets 414 are provided opposite one first heater sheet 412 across the gas pipe 10. The two second heater sheets 414 are disposed opposite the first heater sheet 412 across the gas pipe 10 and are arranged side by side in the lengthwise direction. Furthermore, the two second heater sheets 414 are electrically connected in parallel to an alternating-current (AC) power supply 610.

That is, the number of second heater sheets 414 to be provided is N (N: an integer that is not less than two). The N second heater sheets 414 each have a lengthwise length corresponding to 1/N of the lengthwise length of the first heater sheet 412. In addition, the N second heater sheets 414 are electrically connected in parallel. That is, the second heater sheets 414 are provided in the lengthwise direction in a divided manner and are connected in parallel. According to this configuration, each second heater sheet 414 generates a larger amount of heat as the temperature of the gas pipe 10 thermally coupled thereto is lower; therefore, the temperature of the gas pipe can be made more uniform. Even when a gas pipe serving as a heating target has a complicated shape, the pipe heater 22 is easily brought into close contact with the gas pipe, which may contribute to making the temperature of the heated gas pipe more uniform.

The second heater sheets 414 may have a length corresponding to the length of the first heater sheet 412. In this case, the second heater sheets 414 each include a plurality of second electric heaters electrically connected in parallel.

Desirably, a pipe heater heats a gas pipe uniformly. However, an ambient environment and a complicated shape of a gas pipe serving as a heating target may hinder the pipe heater from heating the gas pipe uniformly. That is, a calorific value of or a heat by a heater that maintains a gas pipe at a fixed temperature differs for each position owing to a degree of close contact between the heater and the gas pipe, an amount of heat dissipated by the heat insulator 552, and heat transfer between a gas and the gas pipe. On the other hand, according to a typical pipe heating technique based on a principle that one heater is controlled using one thermocouple, a pipe is heated in such a manner that a temperature regulator passes the same current through the entire heater so as to regulate a temperature at a certain point on the pipe to a set temperature. A technique of shortening the length of a pipe heater may be employed with regard to this respect; however, an increase in number of control points boosts costs. Alternatively, controlling the entire gas pipe using a heater having self-controllability may achieve a reduction in length of the heater. However, an electric heater having self-controllability has poor temperature accuracy. Hence, the heater having self-controllability is sometime unfit for a gas pipe of which the temperature is maintained at a predetermined absolute value.

The present disclosers have found that, in order to address this respect, the gas pipe can be heated more uniformly without an increase in number of control points, by the pipe heater 22 configured as a complex of the first heater sheet 412 including the electric heater having no self-controllability and the second heater sheets 414 each including the electric heater having self-controllability.

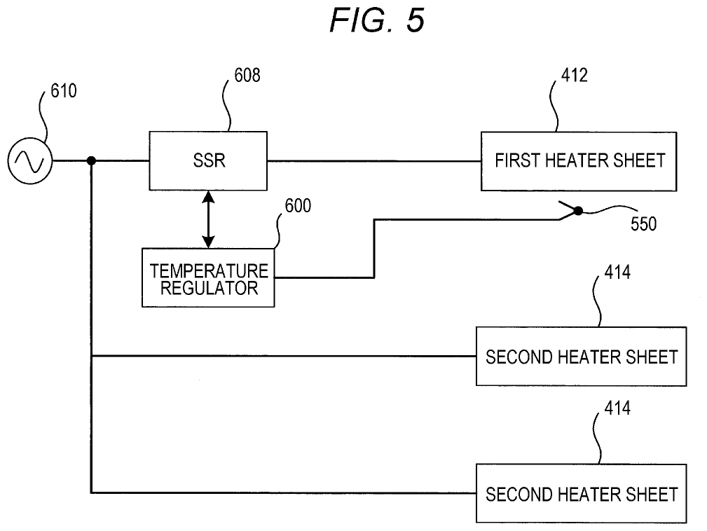

FIG. 5 is a block diagram illustrating the configuration of the pipe heater 22 used in this embodiment.

The AC power supply 610 is connected to the first heater sheet 412 via an solid state relay (SSR) 608. That is, the AC power supply 610 supplies power at a predetermined effective voltage, for example, 100 V. The AC power supply 610 supplies power to the first electric heater 416 of the first heater sheet 412 via the SSR 608.

The SSR 608 is inserted in series in a circuit including the AC power supply 610 and the first heater sheet 412. In addition, the SSR 608 switches between an ON state and an OFF state as to application of the AC voltage from the AC power supply 610, in accordance with a relay output from the temperature regulator 600.

The temperature regulator 600 is configured to compare a temperature detected by the thermocouple 550 with the set temperature and to control the ON and OFF states as to energization of the first heater sheet 412 (i.e., the first electric heater 416) so as to bring the temperature detected by the thermocouple 550 close to the predetermined set temperature. Specifically, when the temperature detected by the thermocouple 550 is lower than the set temperature, the temperature regulator 600 turns on the relay output to energize the first heater sheet. On the other hand, when the temperature detected by the thermocouple 550 is higher than the set temperature, the temperature regulator 600 turns off the relay output to stop the energization of the first heater sheet. The temperature regulator 600 may be achieved by proportional-integral-differential (PID) control having a non-zero integral gain. In this case, a deviation between the detected temperature and the set temperature converges to zero, resulting in high temperature accuracy. The temperature regulator 600 may be configured to successively and variably control the degree of energization of the first heater sheet 412 (i.e., the first electric heater 416) so as to bring the temperature detected by the thermocouple 550 close to the predetermined set temperature, using a power regulator or the like in place of the SSR 608.

The plurality of second heater sheets 414 are connected in parallel to the AC power supply 610. That is, the AC power supply 610 applies a fixed effective voltage to the second electric heater 420 of each second heater sheet 414. In other words, a substantially fixed voltage is applied to each second heater sheet 414 (i.e., each second electric heater 420) irrespective of the temperature detected by the thermocouple 550. The substantially fixed voltage is set to cause the temperature of the gas pipe 10 heated by the second electric heater 420 with the first electric heater 416 not energized, to be lower than the predetermined set temperature by a predetermined temperature. It should be noted that an AC power supply for supplying power to the second heater sheets 414 may be provided additionally, so that the effective voltage applied to the second heater sheets 414 may be different from the effective voltage applied to the first heater sheet 412 during the ON state of the SSR 608. In addition, the substantially fixed voltage applied by the AC power supply 610 is set to cause a ratio between the calorific value of the first electric heater 416 and the calorific value of each second electric heater 420 to fall within a range from ½ or more to 2 or less, with the temperature detected by the thermocouple 550 converging to the predetermined set temperature. When this ratio is less than ½ or is more than 2, the temperature deviation in the circumferential direction of the gas pipe 10 cannot be maintained at a sufficiently small value, or control based on the set temperature may be disabled, or the second heater sheets may fail to satisfactorily exhibit the self-controllability. When this ratio falls within the range from ½ or more to 2 or less, larger the ratio of the calorific value of each second electric heater 420, higher the performance of reducing the temperature deviation, so that the gas pipe 10 can be stably heated with desired self-controllability.

The controller 321 adjusts an operation amount (an output value) indicating power to be output to the first heater sheet 412, based on the temperature detected by the thermocouple 550 (a measured value), and causes the temperature (the measured value) of the gas pipe 10 to follow the predetermined set temperature (a set value).

That is, the present disclosure employs control using two different heaters in such a manner that a heater including an electric heater having self-controllability is disposed on one surface of each of the gas pipes 10 and 40 while a normal heater including an electric heater, such as a nichrome wire, having no self-controllability is disposed on the other surface of each of the gas pipes 10 and 40. Specifically, the second heater sheets 414 having self-controllability heat each of the gas pipes 10 and 40 to a temperature near the predetermined set temperature so as to reduce a spatial temperature deviation while the first heater sheet 412 maintains the gas pipes 10 and 40 at the predetermined set temperature, based on the temperature detected by the thermocouple 550. As described above, the gas pipes 10 and 40 are heated while the thermocouple 550 does not detect and control the degree of energization of the second heater sheets 414, but detects and controls the degree of energization of the first heater sheet 412 that equally heats the gas pipes 10 and 40. This configuration therefore suppresses the temperature unevenness at the gas pipes 10 and 40, and makes the temperature of each of the heated gas pipes 10 and 40 uniform.

That is, the second heater sheets 414 having self-controllability heat each of the gas pipes 10 and 40 to a temperature near the predetermined set temperature while the first heater sheet 412 adjusts the temperature of each of the gas pipes 10 and 40 to the predetermined set temperature. This configuration therefore makes the temperature of each of the gas pipes 10 and 40 serving as a heating target more uniform while maintaining the temperature accuracy.

Accordingly, for example, the process gas is not retained in the furnace opening since the process gas is less likely to undergo liquefaction owing to a reduction in temperature of each of the gas pipes 10 and 40. This configuration thus reduces an influence on a thickness of a film and therefore suppresses deterioration in substrate processing quality.

### (4) Other Embodiments

Although various typical embodiments of the present disclosure have been described above, the present disclosure is not limited to these embodiments, and these embodiments may be used in combination as appropriate.

For example, the second heater sheets 414 described in the foregoing embodiment may be modified as described in the following modified examples. Configurations in the respective modified examples are similar to those described above unless otherwise specified; therefore, the description thereof is omitted.

### Modified Example 1

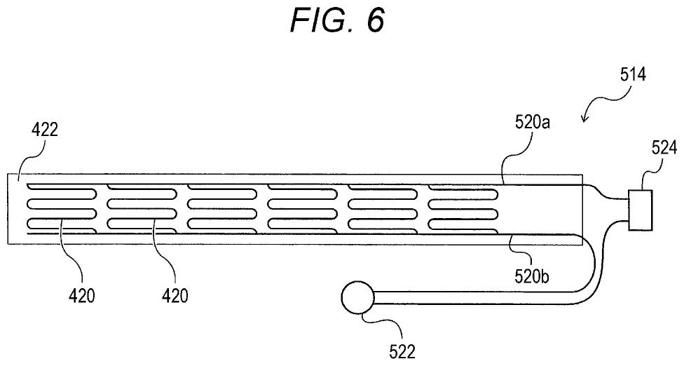

FIG. 6 illustrates a second heater sheet 514 according to Modified Example 1.

The second heater sheet 514 according to Modified Example 1 includes a plurality of second electric heaters 420. The plurality of second electric heaters 420 each have a length corresponding to a length of a first heater sheet 412, and are electrically connected in parallel in the second heater sheet 514. Specifically, the second heater sheet 514 corresponds to one second heater sheet 514 that includes a plurality of second electric heaters 420 having self-controllability and a second insulator 422 electrically insulating and surrounding the plurality of second electric heaters 420. In FIG. 6, the second electric heaters 420 and bus conductors 520a and 520b in the second insulator 422 are each indicated by a solid line for illustration of the configuration. However, a part of each of the bus conductors 520a and 520b as well as the plurality of second electric heaters 420 are surrounded by the second insulator 422.

Specifically, the second heater sheet 514 includes the bus conductors 520a and 520b that are disposed on longitudinal two ends of the second heater sheet 514 and extend substantially in parallel. The second electric heaters 420 each have a meandering shape and have two ends respectively connected to the bus conductors 520a and 520b. That is, each second electric heater 420 having a meandering shape has a first end connected to the bus conductor 520a and a second end connected to the bus conductor 520b. The plurality of second electric heaters 420 are connected in parallel. The bus conductor 520a has an end connected to a connector 524. The bus conductor 520b has an end connected to the connector 524 via a protective circuit component 522 such as a thermostat or a thermal fuse. The protective circuit component 522 is configured to make a circuit when a temperature increases to a certain temperature, to thereby protect the second heater sheet 514 from overheating. In a case where the protective circuit component 522 is a thermostat, the protective circuit component 522 breaks the circuit when the temperature decreases to a certain temperature, to thereby resume energization. Therefore, the protective circuit component 522 is capable of functioning as a simple temperature regulator. The connector 524 is connected to an AC power supply 610.

That is, the second heater sheet 514 according to Modified Example 1 corresponds to one second heater sheet 514 in which a plurality of second electric heaters 420 are provided in a divided manner. A pipe heater 22 including this second heater sheet produces effects similar to those produced by the foregoing pipe heater 22.

### Modified Example 2

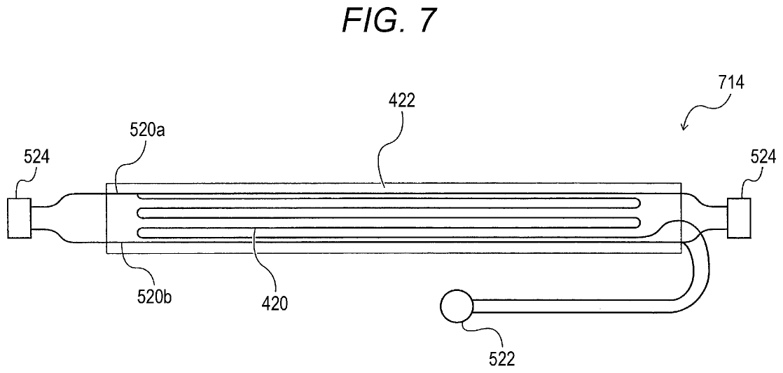

FIG. 7 illustrates a second heater sheet 714 according to Modified Example 2.

The second heater sheet 714 according to Modified Example 2 corresponds to one second heater sheet 714 that includes one second electric heater 420 having self-controllability and a second insulator 422 electrically insulating and surrounding the one second electric heater 420. In the one second heater sheet 714, the one second electric heater 420 is connectable to a second electric heater 420 of another second heater sheet 714. In FIG. 7, the second electric heater 420 and bus conductors 520a and 520b in the second insulator 422 are each indicated by a solid line for illustration of the configuration. However, a part of each of the bus conductors 520a and 520b and the second electric heater 420 are surrounded by the second insulator 422.

Specifically, the second heater sheet 714 includes the bus conductors 520a and 520b that are disposed on longitudinal two ends of the second heater sheet 714 and extend substantially in parallel. The second electric heater 420 has a meandering shape and has two ends respectively connected to the bus conductors 520a and 520b. That is, the second electric heater 420 having a meandering shape has a first end connected to the bus conductor 520a and a second end connected to the bus conductor 520b via a protective circuit component 522. The bus conductors 520a and 520b each have an end connected to a connector 524. The connector 524 is connectable to an AC power supply 610 or is also connectable to a connector 524 of another second heater sheet 714. That is, a plurality of second heater sheets 714 are connected, so that a plurality of second electric heaters 420 are provided in parallel.

That is, the second heater sheet 714 according to Modified Example 2 corresponds to one second heater sheet 714 that includes one second electric heater 420 connectable to another second heater sheet 714 via a connector 524 such that a plurality of second electric heaters are connected. In other words, second heater sheets having self-controllability can be extended in a one-after-another manner. A pipe heater 22 including this second heater sheet produces effects similar to those produced by the foregoing pipe heater 22.

The foregoing embodiment has described the configuration in which the pipe heater 22 is provided for the gas pipes 10 and 40 through which the gases are fed to the process chamber 201; however, the present disclosure is not limited to this configuration. For example, the present disclosure is suitably applicable to a case of using the pipe heater 22 for the gas pipes 11 and 6 through which the gases are fed to the process chamber 201.

The foregoing embodiment has also described the configuration in which the pipe heater 22 is provided for the gas pipes 10 and 40 through which the gases are fed to the process chamber 201; however, the present disclosure is not limited to this configuration. For example, the present disclosure is suitably applicable to a case of using the pipe heater 22 for the exhaust pipe 231. In this case, preferably, the exhaust pipe 231 has a nominal diameter that is not more than 20 mm, for example, that is not more than ¾ inches. The present disclosure is applied to a pipe having a nominal diameter that is not more than 20 mm as described above, which allows the pipe to be heated more uniformly.

The foregoing embodiment has also described the configuration in which the first heater sheet 412 and the second heater sheets 414 are disposed to face each other with the gas pipe 10 sandwiched therebetween such that the lengthwise direction of each of the first heater sheet 412 and the second heater sheets 414 is defined parallel to the lengthwise direction of each of the gas pipes 10 and 40; however, the present disclosure is not limited to this configuration. For example, the present disclosure is suitably applied to a case of placing the first heater sheet 412 and the second heater sheets 414 in a double spiral shape in the lengthwise direction of each of the gas pipes 10 and 40.

The foregoing embodiment has also described the example of providing the first heater sheet 412 and the second heater sheets 414 separately from each other in order to increase the processability and the degree of close contact at the bent portion; however, the present disclosure is not limited to this example. For example, the present disclosure is suitably applicable to a case of integrally forming the first heater sheet 412 and the second heater sheets 414 by coupling their longer sides together, with regard to particularly a pipe having a small number of bent sections. In addition, perforations can be made between the first heater sheet 412 and the second heater sheets 414 so that the first heater sheet 412 and the second heater sheets 414 are separable from each other at a fixed position in processing.

The foregoing embodiment has also described the example of using a sheet-shaped heater sheet as the pipe heater 22; however, the present disclosure is not limited to this example. The pipe heater 22 may previously be formed in a curved shape approximate to the radius of curvature of a pipe. For example, the present disclosure is suitably applicable to a case of using various pipe heaters such as a tape-shaped tape heater, a jacket heater, and a rubber heater that are different in degree of flexibility from each other.

The foregoing embodiment has also described the exemplary step of forming a SiN film on each wafer 200; however, the present disclosure is not limited to this example. For example, the present disclosure is suitably applicable to a case of forming, changing, or etching a film using the pipe heater 22.

The foregoing embodiment has also described the example of feeding power to each second heater sheet 414 at a fixed effective voltage; however, the present disclosure is not limited to this example. Each second heater sheet 414 may include, as in the first heater sheet 412, a thermocouple and a temperature regulator such that power fed to the second heater sheet 414 can be actively and variably controlled based on an actual temperature of the gas pipe 10 at a position where the second heater sheet 414 is provided. In this case, a multiple input-multiple output control system is employed; therefore, parameters can be tuned using a method such as virtual reference feedback tuning.

The foregoing embodiment has also described the example of forming a film using the substrate processing apparatus which is a batch-type vertical apparatus configured to process a plurality of substrates at a time; however, the present disclosure is not limited to this example. The present disclosure is suitably applicable to a case of forming a film using a substrate processing apparatus of a single wafer type configured to process one or several substrates at a time.

The foregoing embodiment has also described the case of heating the pipe serving as a heating target; however, the present disclosure is not limited to this case.

According to the present disclosure, a temperature of a heating target can be made uniform.

What is claimed is:

1. A heater assembly comprising:
a first heater sheet including:
a first electric heater having no self-controllability and
a first insulator electrically insulating and surrounding the first electric heater,
the first heater sheet being deformable in accordance with a shape of a heating target; and
one or more second heater sheets each including
one or more second electric heaters having self-controllability and
a second insulator electrically insulating and surrounding the one or more second electric heaters,
the one or more second heater sheets being deformable in accordance with the shape of the heating target.

2. A substrate processing apparatus comprising:
a pipe including a linear section and a bent section and allowing a fluid to pass through the pipe;
a first heater sheet including:
a first electric heater having no self-controllability, and
a first insulator electrically insulating and surrounding the first electric heater,
the first heater sheet being in close contact with the pipe in a lengthwise direction of the pipe;
one or more second heater sheets each including one or more second electric heaters having self-controllability and
a second insulator electrically insulating and surrounding the one or more second electric heaters,
the one or more second heater sheets being disposed opposite the first heater sheet across the pipe,
the one or more second heater sheets being in close contact with the pipe in the lengthwise direction of the pipe.

3. The substrate processing apparatus of claim 2, further comprising:
a heat insulator covering the pipe together with the first heater sheet and the one or more second heater sheets;
a temperature sensor disposed inside the heat insulator and thermally coupled to the pipe or the first electric heater; and
a temperature regulator configured to control a degree of energization of the first heater sheet so as to bring a temperature detected by the temperature sensor close to a predetermined set temperature.

4. The substrate processing apparatus of claim 2, wherein
the first heater sheet is equal in at least one of a material for the insulators, a lateral width, and a thickness to the one or more second heater sheets.

5. The substrate processing apparatus of claim 2, wherein
a substantially fixed voltage is applied to the one or more second electric heaters irrespective of the temperature detected by the temperature sensor.

6. The substrate processing apparatus of claim 4, wherein
the substantially fixed voltage is set to cause a temperature of the pipe heated by the one or more second electric heaters with the first electric heater not energized, to be lower than the predetermined set temperature by a predetermined temperature.

7. The substrate processing apparatus of claim 4, wherein
the substantially fixed voltage is set to cause a ratio between a calorific value of the first electric heater and calorific values of the one or more second electric heaters to fall within a range from ½ or more to 2 or less, with the temperature detected by the temperature sensor converging to the predetermined set temperature.

8. The substrate processing apparatus of claim 5, wherein
the first heater sheet is substantially equal in width in a shorter side direction to the one or more second heater sheets.

9. The substrate processing apparatus of claim 2, wherein
the pipe includes a bent portion, and
the first heater sheet is disposed on an inner side of the bent portion and the one or more second heater sheets are disposed on an outer side of the bent portion with the first heater sheet disposed opposite the one or more second heater sheets.

10. The substrate processing apparatus of claim 2, wherein
the first heater sheet and the one or more second heater sheets each have a width substantially corresponding to a half of an outer periphery of the pipe, and
the first heater sheet and the one or more second heater sheets are disposed with a lengthwise direction of each heater sheet extending along the pipe.

11. The substrate processing apparatus of claim 2, wherein
the first insulator and the second insulator each comprise a polyimide or fluoroethylene polymer.

12. The substrate processing apparatus of claim 2, wherein
the one or more second electric heaters each have an electric resistance of which a positive temperature coefficient is not less than 0.5%/° C. at the set temperature.

13. The substrate processing apparatus of claim 2, wherein
the pipe is a pipe through which a gas is fed to a process chamber where a substrate is subjected to processing, or has a nominal diameter that is not more than 25 mm.

14. The substrate processing apparatus of claim 2, wherein
the one or more second heater sheets comprise N second heater sheets each having a lengthwise length corresponding to 1/N of a lengthwise length of the first heater sheet, the N second heater sheets being disposed opposite the first heater sheet across the pipe and arranged side by side in the lengthwise direction.

15. The substrate processing apparatus of claim 2, wherein
the one or more second heater sheets comprise N second heater sheets electrically connected in parallel.

16. The substrate processing apparatus of claim 2, wherein
the one or more second heater sheets each include a plurality of the second electric heaters each having a length corresponding to a length of the first heater sheet, the second electric heaters being electrically connected in parallel.

17. A method of processing a substrate comprising:
providing the substrate processing apparatus of claim 1; and
heating the pipe by feeding electrical power to the first electric heater and the second first electric heater.

18. A method of processing a substrate comprising:
providing the substrate processing apparatus of claim 1; and
heating the pipe by feeding electrical power to the first electric heater and the second first electric heater.

19. A method of manufacturing a semiconductor device,
the method comprising:
heating a pipe including a linear section and a bent section and allowing a fluid to pass through the pipe, by a pipe heater including a first heater sheet including a first electric heater having no self-controllability and a first insulator electrically insulating and surrounding the first electric heater, the first heater sheet being in close contact with the pipe in a lengthwise direction of the pipe, and one or more second heater sheets each including one or more second electric heaters having self-controllability and a second insulator electrically insulating and surrounding the one or more second electric heaters, the one or more second heater sheets being disposed opposite the first heater sheet across the pipe, the one or more second heater sheets being in close contact with the pipe in the lengthwise direction of the pipe;
detecting a temperature of the pipe by a temperature sensor disposed inside a heat insulator covering the pipe together with the first heater sheet and the one or more second heater sheets, the temperature sensor being thermally coupled to the pipe or the first electric heater; and
controlling, based on the detected temperature, a degree of energization of the first heater sheet by a temperature regulator, so as to bring the temperature detected by the temperature sensor close to a predetermined set temperature.
